(19) United States
(12) Patent Application Publication
(10) Pub. No.: US 2026/0124699 A1
(43) Pub. Date: May 7, 2026

(54) LASER PROCESSING APPARATUS AND ELECTRONIC DEVICE MANUFACTURING METHOD

(71) Applicant: Gigaphoton Inc., Tochigi (JP)

(72) Inventor: Tomonari TANAKA, Tochigi (JP)

(73) Assignee: Gigaphoton Inc., Tochigi (JP)

(21) Appl. No.: 19/348,706

(22) Filed: Oct. 2, 2025

(30) Foreign Application Priority Data
Nov. 7, 2024 (JP) 2024-195486

(51) Int. Cl. B23K 26/06; B23K 26/382; B23K 101/40; B23K 101/42; H01L 21/48

(52) U.S. Cl. CPC B23K 26/0648; B23K 26/0665; B23K 26/382; H10W 70/095; B23K 2101/40; B23K 2101/42

(57) ABSTRACT

A laser processing apparatus according to one aspect of the present disclosure performs hole processing on a workpiece using a pulse laser beam output from a laser apparatus, and includes a Z polarizer disposed on an optical path of the pulse laser beam and configured to convert a polarization state of the pulse laser beam to azimuthal polarization, a diffractive optical element configured to split the azimuthally polarized pulse laser beam transmitted through the Z polarizer into a plurality of laser beams, and a light condensing optical system configured to generate a plurality of light condensing spots on the workpiece by condensing the laser beams.

### CROSS-REFERENCE TO RELATED APPLICATIONS

The present application claims the benefit of Japanese Patent Application No. 2024-195486, filed on Nov. 7, 2024, the entire contents of which are hereby incorporated by reference.

### BACKGROUND

### 1. Technical Field

The present disclosure relates to a laser processing apparatus and an electronic device manufacturing method.

### 2. Related Art

Recently, an improvement in resolutions of semiconductor exposure devices has been desired with miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248.4 nm and an ArF excimer laser apparatus that outputs a laser beam having a wavelength of about 193.4 nm are used.

In addition, an excimer laser beam has a pulse width of about several tens of ns and, due to its short wavelength, is sometimes used for direct processing of polymer materials and glass materials or the like.

A chemical bond in a polymer material can be cut by an excimer laser beam having photon energy higher than bond energy. Therefore, it is known that non-heating processing of a polymer material is made possible by an excimer laser beam, and a processing shape becomes smooth.

In addition, since glass, ceramics, and the like have a high absorptance to an excimer laser beam, it is known that even a material that is difficult to be processed by a visible and infrared laser beam can be processed by an excimer laser beam.

### LIST OF DOCUMENTS

### Patent Documents

Patent Document 1: U.S. Pat. No. 7,880,117
Patent Document 2: Japanese Unexamined Patent Application Publication No. 2022-060850
Patent Document 3: International Publication No. WO 2023/099946

### SUMMARY

A laser processing apparatus according to one aspect of the present disclosure performs hole processing on a workpiece using a pulse laser beam output from a laser apparatus, and includes a Z polarizer, a diffractive optical element, and a light condensing optical system. The Z polarizer is disposed on an optical path of the pulse laser beam and is configured to convert a polarization state of the pulse laser beam to azimuthal polarization. The diffractive optical element is configured to split the azimuthally polarized pulse laser beam transmitted through the Z polarizer into a plurality of laser beams. The light condensing optical system is configured to generate a plurality of light condensing spots on the workpiece by condensing the laser beams.

An electronic device manufacturing method according to one aspect of the present disclosure includes producing an interposer by laser processing an interposer substrate with a laser processing apparatus, coupling and electrically connecting the interposer and an integrated circuit chip to each other, and coupling and electrically connecting the interposer and a circuit board to each other. The laser processing apparatus performs hole processing on a workpiece using a pulse laser beam output from a laser apparatus, and includes a Z polarizer disposed on an optical path of the pulse laser beam and configured to convert a polarization state of the pulse laser beam to azimuthal polarization, a diffractive optical element configured to split the azimuthally polarized pulse laser beam transmitted through the Z polarizer into a plurality of laser beams, and a light condensing optical system configured to generate a plurality of light condensing spots on the workpiece by condensing the laser beams.

### BRIEF DESCRIPTION OF THE DRAWINGS

Embodiments of the present disclosure will be described below merely as examples with reference to the accompanying drawings.

FIG. 1 is a diagram schematically illustrating a configuration of a laser processing system according to a comparative example.

FIG. 2 is a diagram schematically illustrating a configuration of a laser apparatus.

FIG. 3 is a diagram schematically illustrating a configuration of a laser processing system according to a first embodiment.

FIG. 4 is a diagram illustrating a configuration example of a Z polarizer.

FIG. 5 is a diagram illustrating an action of the Z polarizer.

FIG. 6 is a diagram describing position adjustment of the Z polarizer.

FIG. 7 is a diagram illustrating an example of a laser beam incident on an inner wall of a hole during hole processing.

FIG. 8 is a diagram illustrating an example of a laser beam incident on an inner wall of a hole during hole processing.

FIG. 9 is a diagram describing a polarization state on an inner wall when a linearly polarized laser beam is incident on a hole.

FIG. 10 is a diagram describing a polarization state on an inner wall when an azimuthally polarized laser beam is incident on a hole.

FIG. 11 is a diagram illustrating a configuration of a Z polarizer according to a modification.

FIG. 12 is a diagram illustrating an action of the Z polarizer according to the modification.

FIG. 13 is a diagram schematically illustrating a configuration of a laser processing system according to a second embodiment.

FIG. 14 is a diagram illustrating a configuration example of a multi-spot polarization converter.

FIG. 15 is a diagram illustrating a configuration of a multi-spot polarization converter according to a first modification.

FIG. 16 is a diagram illustrating a configuration of a multi-spot polarization converter according to a second modification.

FIG. 17 is a diagram schematically illustrating a configuration of an electronic device.

FIG. 18 is a flowchart illustrating an electronic device manufacturing method.

### DESCRIPTION OF EMBODIMENTS

### <Contents>

1. Comparative Example
   1.1 Configuration
      1.1.1 Laser Processing System
      1.1.2 Diffractive Optical Element
      1.1.3 Laser Apparatus
   1.2 Operation
   1.3 Problem
2. First Embodiment
   2.1 Configuration
   2.2 Operation
   2.3 Effect
   2.4 Modification
3. Second Embodiment
   3.1 Configuration
   3.2 Operation
   3.3 Effect
   3.4 Modification
4. Electronic Device Manufacturing Method

Hereinafter, embodiments of the present disclosure will be described in detail with reference to the drawings. The embodiments described below show some examples of the present disclosure and do not limit contents of the present disclosure. Not all configurations and operations described in each embodiment are necessarily essential as configurations and operations of the present disclosure. Here, the same components are denoted by the same reference numerals, and any redundant description thereof is omitted.

### 1. Comparative Example

### 1.1 Configuration

### 1.1.1 Laser Processing System

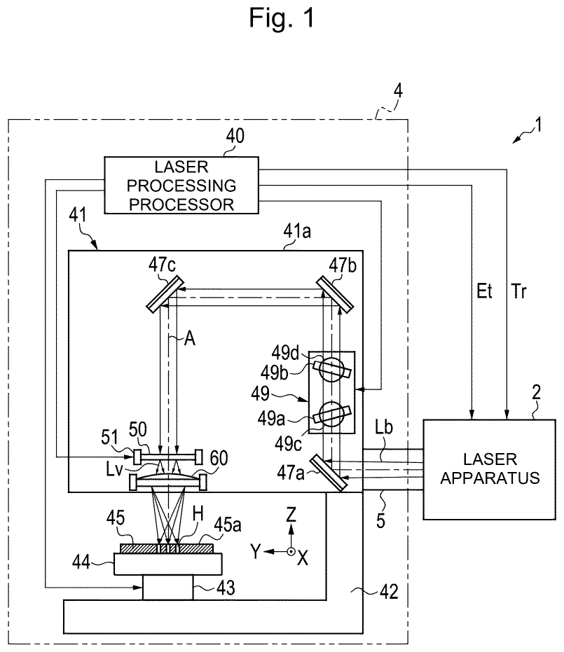

FIG. 1 schematically illustrates a configuration of a laser processing system 1 according to the comparative example. The comparative example is an example recognized by the applicant as known only by the applicant, and is not a publicly known example admitted by the applicant.

The laser processing system 1 mainly includes a laser apparatus 2 and a laser processing apparatus 4. The laser processing system 1 is used for hole processing of forming holes such as via holes on a glass substrate for an interposer.

The laser apparatus 2 outputs an ultraviolet pulse laser beam. For example, the laser apparatus 2 is a discharge excitation type laser apparatus that outputs an ultraviolet pulse laser beam using a laser medium such as F₂, ArF, KrF, XeCl, or XeF. In the present disclosure, the laser apparatus 2 is a KrF excimer laser apparatus that outputs an ultraviolet pulse laser beam having a center wavelength of 248.4 nm. Hereinafter, the ultraviolet pulse laser beam output by the laser apparatus 2 is simply referred to as a laser beam Lb.

The laser apparatus 2 and the laser processing apparatus 4 are connected by an optical path tube 5. The optical path tube 5 is disposed on an optical path of the laser beam Lb between an exit port of the laser apparatus 2 and an entrance port of the laser processing apparatus 4.

The laser processing apparatus 4 includes a laser processing processor 40, an optical device 41, a frame 42, an XYZ stage 43, and a table 44. To the frame 42, the optical device 41 and the XYZ stage 43 are fixed.

The table 44 supports a workpiece 45. The workpiece 45 is an object to be processed where hole processing is performed. The workpiece 45 is a glass substrate for an interposer, and is, for example, a non-alkali glass substrate. The workpiece 45 may also be a substrate formed of quartz glass, organic materials, silicon monocrystal, ceramics, metals, or the like. A plurality of holes H are formed in the workpiece 45 by so-called multi-point hole processing.

The XYZ stage 43 supports the table 44. The workpiece 45 is fixed on the table 44. The XYZ stage 43 allows the table 44 to move in X, Y, and Z directions, and changes a position of the workpiece 45 by moving the table 44. The X, Y, and Z directions are orthogonal to each other. The X and Y directions are parallel to a surface 45a of the workpiece 45. The Z direction is orthogonal to the surface 45a. The XYZ stage 43 is a moving stage that allows the workpiece 45 to be moved in a direction orthogonal to an optical axis of a light condensing lens 60. The XYZ stage 43 is connected to the laser processing processor 40.

The optical device 41 includes a housing 41a, high reflective mirrors 47a, 47b, and 47c, an attenuator 49, a diffractive optical element (DOE) 50, a moving stage 51, and the light condensing lens 60.

Each component in the optical device 41 is fixed to an unillustrated holder and is disposed at a predetermined position in the housing 41a.

The high reflective mirror 47a reflects the laser beam Lb that has passed through the optical path tube 5, and is disposed so that the reflected laser beam Lb passes through the attenuator 49 and is incident on the high reflective mirror 47b. The optical path tube 5 and the housing 41a are purged with a purge gas, for example. The purge gas is an inert gas such as an N₂ gas, which hardly absorbs the laser beam Lb.

The attenuator 49 is disposed on an optical path between the high reflective mirror 47a and the high reflective mirror 47b in the housing 41a. The attenuator 49 includes, for example, two partial reflective mirrors 49a and 49b and rotating stages 49c and 49d of the partial reflective mirrors. The partial reflective mirrors 49a and 49b are optical elements a transmittance of which changes according to an incident angle of the laser beam Lb. For the partial reflective mirrors 49a and 49b, the incident angle of the laser beam Lb is adjusted by the rotating stages 49c and 49d.

The high reflective mirrors 47b and 47c reflect the laser beam Lb that has passed through the attenuator 49, and are disposed so that the reflected laser beam Lb is incident on the DOE 50.

The DOE 50 is disposed so that a center coincides with an optical axis A of the laser beam Lb on an optical path of the laser beam Lb reflected by the high reflective mirror 47c. The DOE 50 splits the laser beam Lb incident from the high reflective mirror 47c into a plurality of laser beams Lv of different exit angles by diffracting the laser beam Lb. That is, the DOE 50 splits the laser beam Lb in the X and Y directions. In the present disclosure, the optical axis A of the laser beam Lb refers to an axis that passes through a center of a luminous flux of the laser beam Lb.

The moving stage 51 holds the DOE 50 movably in a direction orthogonal to the optical axis A of the laser beam Lb. Specifically, the moving stage 51 holds the DOE 50 movably in the X and Y directions.

The moving stage 51 is connected to the laser processing processor 40. The laser processing processor 40 controls the moving stage 51 when performing adjustment so that the center of the DOE 50 coincides with the optical axis A of the laser beam Lb. Here, coincidence means that an amount of deviation between the center of the DOE 50 and the optical axis A is 10% or less of a 1/e² beam diameter of the laser beam Lb. The 1/e² beam diameter is a radius of the beam at a point where intensity is 1/e² times peak intensity.

The light condensing lens 60 is disposed so that the laser beams Lv output from the DOE 50 are incident and a focal plane is positioned on the surface 45a of the workpiece 45. The light condensing lens 60 is, for example, an Fθ lens, which condenses each of the laser beams Lv output from the DOE 50 and generates a multi-point pattern with a plurality of light condensing spots arranged in a grid. The light condensing lens 60 is an example of a “light condensing optical system” according to technology of the present disclosure.

### 1.1.2 Diffractive Optical Element

A DOE functions by utilizing a diffraction phenomenon of light. A DOE can output various patterns of diffracted light by designing fine structures through simulation. In addition, a DOE can control light intensity of each diffracted light. The DOE 50 of the present disclosure is produced by engraving a pattern on a substrate of quartz or the like.

### 1.1.3 Laser Apparatus

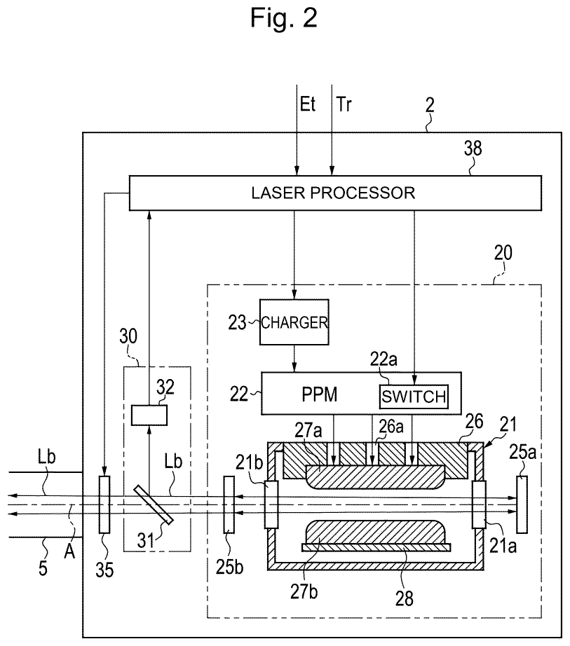

FIG. 2 schematically illustrates a configuration of the laser apparatus 2. The laser apparatus 2 includes an oscillator 20, a monitor module 30, a shutter 35, and a laser processor 38. The oscillator 20 includes a chamber 21, an optical resonator formed of a rear mirror 25a and an output coupling mirror 25b, a charger 23, and a power supply unit (PPM: Pulsed Power Module) 22.

The chamber 21 is provided with windows 21a and 21b. A laser gas as a laser medium is sealed in the chamber 21.

In addition, an opening is formed in the chamber 21, and an electrically insulating plate 26 embedded with a plurality of feedthroughs 26a is provided so as to close this opening. The PPM 22 is disposed on the electrically insulating plate 26. In the chamber 21, a pair of discharge electrodes 27a and 27b as main electrodes and a ground plate 28 are disposed. A discharge surface shape of the discharge electrodes 27a and 27b is rectangular.

The discharge electrodes 27a and 27b are disposed so that their discharge surfaces face each other to excite the laser medium by discharge. The discharge electrode 27a is supported by the electrically insulating plate 26 on a surface on a side opposite to the discharge surface. The discharge electrode 27a is connected to the feedthroughs 26a. The discharge electrode 27b is supported by the ground plate 28 on a surface on the side opposite to the discharge surface.

The PPM 22 includes a switch 22a, and a charging capacitor, a pulse transformer, a magnetic compression circuit, and a peaking capacitor that are not illustrated. The peaking capacitor is connected to the feedthroughs 26a via an unillustrated connecting portion. The charger 23 charges the charging capacitor based on control from the laser processor 38.

The switch 22a is controlled to be on/off by the laser processor 38. The laser processor 38 turns on the switch 22a in response to a light emission trigger Tr transmitted from the laser processing processor 40.

When the switch 22a is turned on, current flows from the charging capacitor to a primary side of the pulse transformer, and a reverse current flows to a secondary side of the pulse transformer due to electromagnetic induction. The magnetic compression circuit is connected to the secondary side of the pulse transformer and compresses a pulse width of a current pulse. The peaking capacitor is charged by this current pulse. When a voltage of the peaking capacitor reaches a breakdown voltage of the laser gas, dielectric breakdown occurs in the laser gas between the discharge electrodes 27a and 27b, resulting in discharge. This discharge generates one pulse of the laser beam Lb.

The rear mirror 25a is formed by coating a high reflective film on a planar substrate. The output coupling mirror 25b is formed by coating a partial reflective film on a planar substrate. The chamber 21 is disposed between the rear mirror 25a and the output coupling mirror 25b. The laser beam Lb generated in the chamber 21 is amplified by the optical resonator and is output from the output coupling mirror 25b.

The monitor module 30 includes a beam splitter 31 and a photosensor 32. The beam splitter 31 is disposed on an optical path of the laser beam Lb output from the output coupling mirror 25b, and reflects a portion of the laser beam Lb. The photosensor 32 is disposed at a position where the laser beam Lb reflected by the beam splitter 31 enters. The photosensor 32 measures pulse energy of the laser beam Lb and transmits a measurement value to the laser processor 38.

The laser processor 38 executes control so that the pulse energy of the laser beam Lb output from the laser apparatus 2 becomes target pulse energy Et by changing a charging voltage of the charger 23 based on the measurement value of the pulse energy by the photosensor 32.

The shutter 35 is disposed on an optical path of the laser beam Lb transmitted through the beam splitter 31. The shutter 35 opens and closes in response to commands from the laser processor 38. The laser processor 38 controls output of the laser beam Lb from the laser apparatus 2 by controlling the shutter 35. The laser beam Lb output from the laser apparatus 2 is linearly polarized.

### 1.2 Operation

Next, the operation of the laser processing system 1 according to the comparative example will be described. First, the laser processing processor 40 controls the XYZ stage 43 so that the focal plane of the light condensing lens 60 coincides with the surface 45a of the workpiece 45. Next, the laser processing processor 40 transmits the target pulse energy Et to the laser processor 38 and controls a transmittance Ta of the attenuator 49 so that a fluence on the surface 45a becomes a target fluence Ft.

Here, the fluence refers to a pulse energy density per pulse at a single light condensing spot on the surface 45a of the workpiece 45. If a transmittance of the optical device 41 is T₀ when the transmittance of the attenuator 49 is 100%, the number of the light condensing spots is Q, and area of the light condensing spot is S, the target fluence Ft is expressed by the following equation (1).

Ft=Et×Ta×T₀/(Q×S) (1)

Upon receiving the target pulse energy Et, the laser processor 38 controls the charger 23 so that the pulse energy of the laser beam Lb becomes the target pulse energy Et. Next, the laser processor 38 causes the oscillator 20 to spontaneously oscillate by inputting a trigger to the switch 22a. At that time, the shutter 35 is in a closed state.

A portion of the laser beam Lb output from the chamber 21 via the output coupling mirror 25b is sampled in the monitor module 30 to measure the pulse energy. The laser processor 38 controls the charger 23 so that a difference ΔE between the pulse energy and the target pulse energy Et approaches zero. Then, when the difference ΔE falls within an allowable range, the laser processor 38 transmits a permission signal to the laser processing processor 40 and turns the shutter 35 to an open state.

Upon receiving the permission signal, the laser processing processor 40 transmits the light emission trigger Tr of a predetermined repetition frequency and a predetermined pulse number to the laser apparatus 2. As a result, the linearly polarized laser beam Lb is output from the laser apparatus 2 in synchronization with the light emission trigger Tr and enters the laser processing apparatus 4 through the optical path tube 5. This laser beam Lb is reflected by the high reflective mirror 47a, is attenuated by the attenuator 49, and is then reflected by the high reflective mirrors 47b and 47c. The laser beam Lb reflected by the high reflective mirror 47c is incident on the DOE 50.

The DOE 50 splits the incident laser beam Lb into the laser beams Lv on the surface 45a of the workpiece 45. The light condensing lens 60 forms the multi-point pattern by condensing each of the laser beams Lv on the surface 45a of the workpiece 45. When each light condensing spot of the multi-point pattern is irradiated with the laser beams Lv of the predetermined pulse number and the fluence exceeds a processing threshold, laser ablation occurs and the hole H is formed.

Next, the laser processing processor 40 controls the XYZ stage 43 and the laser apparatus 2 to repeat change of an irradiation position of the multi-point pattern and irradiation in a step-and-repeat manner, forming the holes H in an entire processing area where hole processing is required.

### 1.3 Problem

In the laser processing system 1 according to the comparative example, if the workpiece 45 is a glass substrate for an interposer or the like, laser irradiation time during the hole processing becomes long, taking time to complete the hole processing. Therefore, it is desired to shorten the laser irradiation time to improve a processing speed.

The present disclosure provides a laser processing apparatus capable of improving a processing speed in hole processing of a glass substrate or the like, and an electronic device manufacturing method.

### 2. First Embodiment

A laser processing system 1a according to the first embodiment of the present disclosure will be described. Configurations similar to those described above are denoted by identical reference signs, and duplicate description thereof is omitted unless otherwise specified.

### 2.1 Configuration

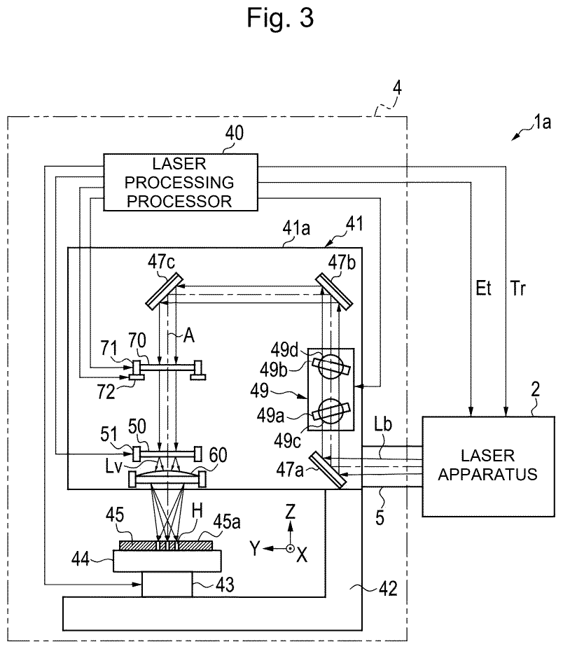

FIG. 3 schematically illustrates a configuration of the laser processing system 1a according to the first embodiment. The laser processing system 1a has the configuration similar to that of the laser processing system 1 according to the comparative example, except for the optical device 41.

The optical device 41 according to the present embodiment differs from the optical device 41 according to the comparative example only in that it includes a Z polarizer 70, a rotating stage 71, and a moving stage 72 in addition to the configuration described above.

The Z polarizer 70 is disposed on an optical path of the laser beam Lb between the high reflective mirror 47c and the DOE 50. The Z polarizer 70 only needs to be disposed more on an upstream side of the laser beam Lb than the DOE 50. The Z polarizer 70 is a polarization conversion element that converts a polarization state of the laser beam Lb from linear polarization to azimuthal polarization. The azimuthal polarization refers to a concentric polarization state where a polarization direction is along a circumferential direction of the beam.

In addition, the Z polarizer 70 is disposed so that the center coincides with the optical axis A of the laser beam Lb. Here, coincidence means that an amount of deviation between the center of the Z polarizer 70 and the optical axis A is 10% or less of the 1/e² beam diameter of the laser beam Lb.

The rotating stage 71 holds the Z polarizer 70 rotatably with the optical axis A as a rotation axis. The Z polarizer 70 is disposed so that the center coincides with the rotation axis. In the present embodiment, the rotation axis is parallel to the Z direction.

The moving stage 72 holds the Z polarizer 70 movably in the direction orthogonal to the optical axis A. Specifically, the moving stage 72 holds the Z polarizer 70 movably in the X and Y directions. While the moving stage 72 supports the rotating stage 71 in the present embodiment, the rotating stage 71 may support the moving stage 72.

The moving stage 72 corresponds to a “first moving stage” according to the technology of the present disclosure. The moving stage 51 corresponds to a “second moving stage” according to the technology of the present disclosure.

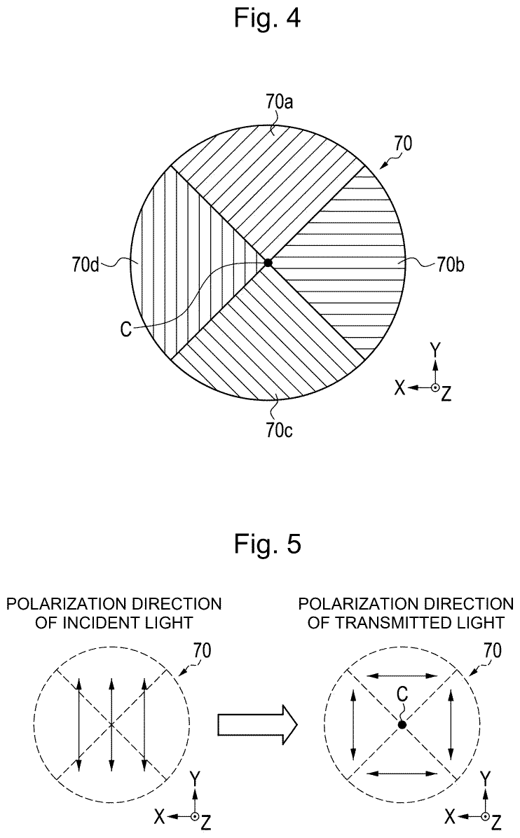

FIG. 4 illustrates a configuration example of the Z polarizer 70. As illustrated in FIG. 4, the Z polarizer 70 is formed by combining four ½ wave plates 70a to 70d of different optical axis directions. Specifically, the ½ wave plates 70a to 70d are four sector-shaped plates obtained by evenly dividing a circular plate into four parts with four straight lines passing through a center C. For example, each of the ½ wave plates 70a to 70d is formed from optically anisotropic birefringent crystal. In the present disclosure, the optical axis refers to an axis where a propagation speed of light does not depend on the polarization direction in the birefringent crystal.

Solid lines illustrated in each of the ½ wave plates 70a to 70d indicate the optical axis direction. Each of the ½ wave plates 70a to 70d has the optical axis direction differing by 45° from that of the adjacent ½ wave plate. Each of the ½ wave plates 70a to 70d converts incident linearly polarized light into linearly polarized light that is symmetrical to the optical axis.

The Z polarizer 70 may be formed by combining four or more ½ wave plates. It is preferable that the number of the ½ wave plates to be combined is larger. This is because the polarization direction of azimuthally polarized light to be generated approaches a direction along a circumference as the number of the ½ wave plates to be combined is larger. However, practically, the number of the ½ wave plates to be combined is preferably between 4 and 12. For example, when eight ½ wave plates are to be combined, the optical axis direction of each ½ wave plate may differ by 22.5°. Also, when twelve ½ wave plates are to be combined, the optical axis direction of each ½ wave plate may differ by 15°.

### 2.2 Operation

The operation of the laser processing system 1a according to the first embodiment is the same as the operation of the laser processing system 1 according to the comparative example, except for the action by the Z polarizer 70. Hereinafter, differences from the comparative example will be described.

The linearly polarized laser beam Lb that has entered the laser processing apparatus 4 from the laser apparatus 2 passes through the high reflective mirror 47a, the attenuator 49, and the high reflective mirrors 47b and 47c, and is incident on the Z polarizer 70. The polarization state of the laser beam Lb is converted to the azimuthal polarization by the Z polarizer 70. The laser beam Lb that has transmitted through the Z polarizer 70 is split into the laser beams Lv by being transmitted through the DOE 50. The polarization state of each of the laser beams Lv is the azimuthal polarization.

The light condensing lens 60 forms the multi-point pattern by condensing each of the laser beams Lv on the surface 45a of the workpiece 45. As a result, when each light condensing point is irradiated with the azimuthally polarized laser beams Lv of the predetermined pulse number and the fluence exceeds the processing threshold, the laser ablation occurs and the hole H is formed.

FIG. 5 illustrates the action of the Z polarizer 70. For example, the Z polarizer 70 converts the linearly polarized light of the polarization direction being the Y direction to concentric azimuthally polarized light with the center C as the axis. In order to generate the azimuthally polarized light of the even polarization direction with the center C as the axis as illustrated in FIG. 5, the direction of the linearly polarized light incident on the Z polarizer 70 needs to form a predetermined angle with respect to the optical axis direction of each of the ½ wave plates 70a to 70d. For example, the direction of the linearly polarized light incident on the Z polarizer 70 may be parallel to the optical axis direction of the ½ wave plate 70d. In the present embodiment, the laser processing processor 40 controls the rotating stage 71 so that the angle of the polarization direction of the laser beam Lb incident on the Z polarizer 70 with respect to the optical axis is the predetermined angle.

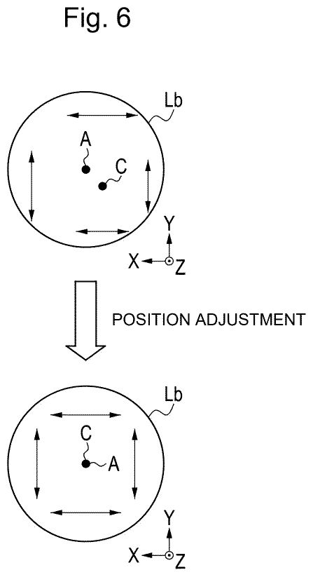

FIG. 6 describes position adjustment of the Z polarizer 70. As illustrated in FIG. 6, if the optical axis A of the laser beam Lb incident on the Z polarizer 70 is offset from the center C of the Z polarizer 70, deviation occurs in the azimuthally polarized light. In the present embodiment, the laser processing processor 40 controls the moving stage 72 so that the optical axis A of the laser beam Lb incident on the Z polarizer 70 coincides with the center C of the Z polarizer 70.

### 2.3 Effect

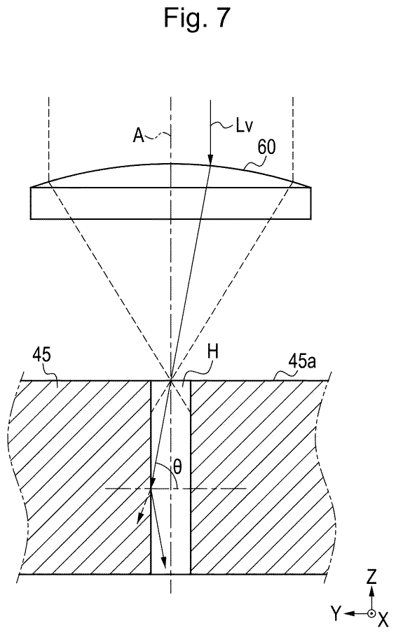

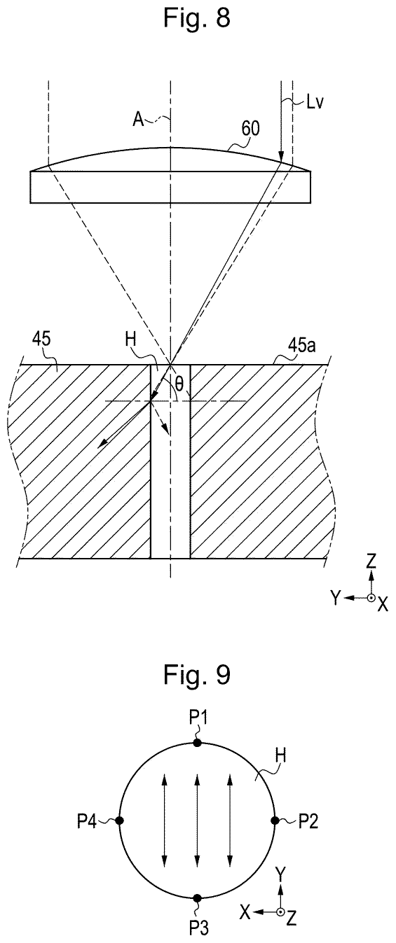

As illustrated in FIG. 7 and FIG. 8, the laser ablation occurs in the workpiece 45 when the fluence exceeds the processing threshold near the light condensing spot of the laser beams Lv. Further, the laser ablation also occurs when the fluence exceeds the processing threshold at a position where the laser beams Lv Fresnel-reflected on an inner wall of the processed hole H are condensed again.

A reflectance of the laser beams Lv on the inner wall of the hole H generally increases as an incident angle θ on the inner wall becomes larger. The incident angle θ is larger in the case illustrated in FIG. 7 than in the case illustrated in FIG. 8, resulting in a higher reflectance. Additionally, since S-polarized light has a higher reflectance than P-polarized light in Fresnel reflection, the reflectance of the laser beams Lv incident on the inner wall of the hole His higher when the polarization state at incidence is closer to S polarization.

In the comparative example, as illustrated in FIG. 9, the linearly polarized laser beams Lv are incident on the hole H. In this case, the polarization state of the laser beams Lv is P polarization at points P1 and P3 facing in the polarization direction on the inner wall of the hole H, and is the S polarization at points P2 and P4 facing in a direction orthogonal to the polarization direction. Therefore, the reflectance of the laser beams Lv becomes lower as getting closer to the points P1 and P3. Thus, in the comparative example, since the reflectance of the laser beams Lv decreases depending on the position on the inner wall, energy contributing to the laser ablation decreases at the position where the laser beams Lv are condensed again.

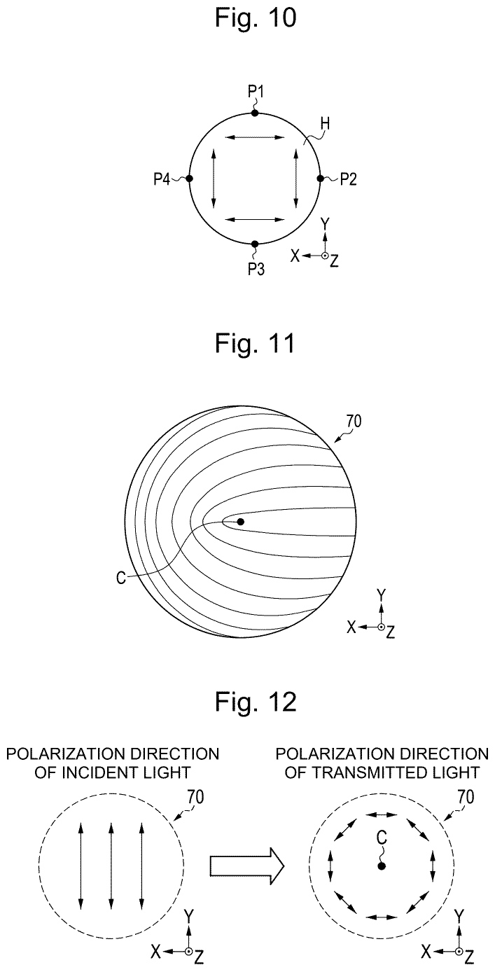

In contrast, in the present embodiment, as illustrated in FIG. 10, the azimuthally polarized laser beams Lv are incident on the hole H. In this case, the polarization state of the laser beams Lv is the S polarization at all the points P1 to P4. In the present embodiment, since the laser beams Lv are incident on the inner wall of the hole H as the S-polarized light at an increased percentage, the reflectance is higher compared to the comparative example, and the energy contributing to the laser ablation increases at the position where the laser beams Lv are condensed again. Therefore, according to the present embodiment, the laser irradiation time can be shortened, and the processing speed can be improved. Further, the pulse number of the laser beam Lb required for the hole processing can be reduced.

### 2.4 Modification

FIG. 11 illustrates the configuration of the Z polarizer 70 according to the modification. While the Z polarizer 70 is formed by combining the ½ wave plates in the embodiment, the Z polarizer 70 illustrated in FIG. 11 is formed by a polarization converter. Solid lines illustrated in the Z polarizer 70 in FIG. 11 indicate the optical axis direction. The optical axis direction is continuously changing.

FIG. 12 illustrates the action of the Z polarizer 70 according to the modification. In the present modification, the polarization direction of the azimuthally polarized light after being converted by the Z polarizer 70 is along the circumference. As a result, the laser beams Lv are incident on the inner wall of the hole H as the S-polarized light at an increased percentage, so that the processing speed is further improved.

In addition, when the Z polarizer 70 is formed by combining the ½ wave plates as in the embodiment, energy loss of the laser beams Lv occurs at a junction of the two ½ wave plates. In contrast, since the Z polarizer 70 according to the modification has no junction, the energy loss of the laser beams Lv is reduced. Thus, the processing speed is further improved.

### 3. Second Embodiment

A laser processing system 1b according to the second embodiment of the present disclosure will be described. Configurations similar to those described above are denoted by identical reference signs, and duplicate description thereof is omitted unless otherwise specified.

### 3.1 Configuration

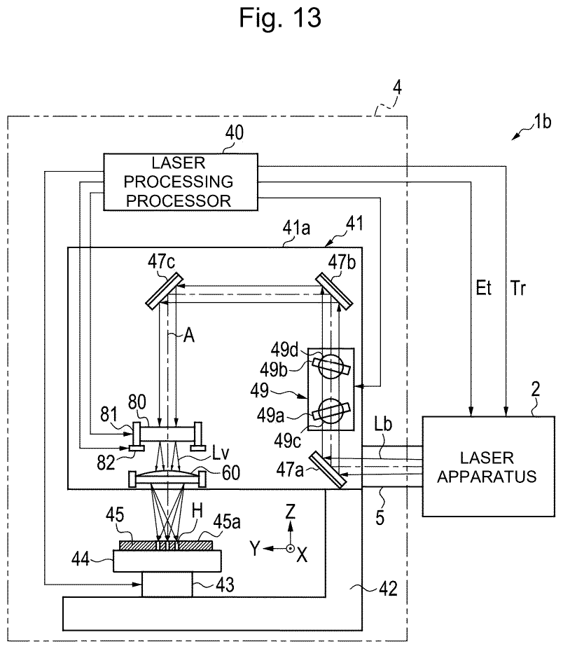

FIG. 13 schematically illustrates the configuration of the laser processing system 1b according to the second embodiment. The laser processing system 1b has the configuration similar to that of the laser processing system 1a according to the first embodiment, except for the optical device 41.

The optical device 41 according to the present embodiment differs from the optical device 41 according to the first embodiment in that a multi-spot polarization converter 80 is provided instead of the Z polarizer 70 and the DOE 50. In addition, the optical device 41 according to the present embodiment includes a rotating stage 81 and a moving stage 82.

The multi-spot polarization converter 80 is disposed on an optical path of the laser beam Lb between the high reflective mirror 47c and the light condensing lens 60. The multi-spot polarization converter 80 only needs to be disposed more on the upstream side of the laser beam Lb than the light condensing lens 60. The multi-spot polarization converter 80 is an optical element obtained by integrating the Z polarizer 70 and the DOE 50. The multi-spot polarization converter 80 converts the polarization state of the laser beam Lb from the linear polarization to the azimuthal polarization, and also splits the laser beam Lb into the laser beams Lv of different exit angles.

In addition, the multi-spot polarization converter 80 is disposed so that the center coincides with the optical axis A of the laser beam Lb. Here, coincidence means that the amount of deviation between the center of the multi-spot polarization converter 80 and the optical axis A is 10% or less of the 1/e² beam diameter of the laser beam Lb.

The rotating stage 81 holds the multi-spot polarization converter 80 rotatably with the optical axis A as the rotation axis. In the present embodiment, the rotation axis is parallel to the Z direction.

The moving stage 82 holds the multi-spot polarization converter 80 movably in the direction orthogonal to the optical axis A. Specifically, the moving stage 82 holds the multi-spot polarization converter 80 movably in the X and Y directions. While the moving stage 82 supports the rotating stage 81 in the present embodiment, the rotating stage 81 may support the moving stage 82.

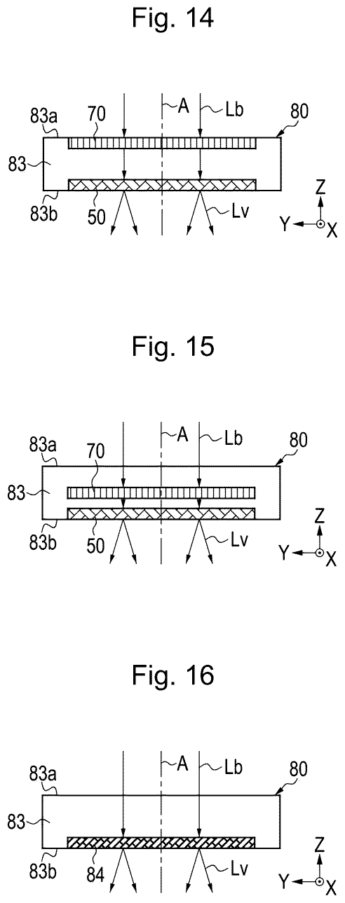

FIG. 14 illustrates a configuration example of the multi-spot polarization converter 80. The multi-spot polarization converter 80 includes a light-transmissive substrate 83. The Z polarizer 70 and the DOE 50 are formed in the substrate 83. The Z polarizer 70 is formed along an incident surface 83a of the substrate 83 on which the laser beam Lb is incident. The DOE 50 is formed along an exit surface 83b of the substrate 83 from which the laser beams Lv are output. The Z polarizer 70 and the DOE 50 face each other and are disposed so that the centers coincide with each other.

### 3.2 Operation

The operation of the laser processing system 1b according to the second embodiment is the same as the operation of the laser processing system 1a according to the first embodiment, except for adjustment control of the multi-spot polarization converter 80. Hereinafter, differences from the first embodiment will be described.

In the present embodiment, the laser processing processor 40 controls the rotating stage 81 so that the angle of the polarization direction of the laser beam Lb incident on the Z polarizer 70 of the multi-spot polarization converter 80 with respect to the optical axis is the predetermined angle.

In addition, in the present embodiment, the laser processing processor 40 controls the moving stage 82 so that the optical axis A of the laser beam Lb incident on the Z polarizer 70 and the DOE 50 of the multi-spot polarization converter 80 coincides with the center C of the Z polarizer 70.

### 3.3 Effect

According to the present embodiment, the same effects as those of the first embodiment can be obtained.

Further, in the first embodiment, since the Z polarizer 70 and the DOE 50 that are separately provided are used, the laser beam Lb is Fresnel-reflected on a total of four surfaces: the incident and exit surfaces of the Z polarizer 70 and the incident and exit surfaces of the DOE 50. In contrast, in the present embodiment, the laser beam Lb is Fresnel-reflected on the total of two surfaces: the incident and exit surfaces of the multi-spot polarization converter 80. Thus, in the present embodiment, since the number of surfaces where the laser beam Lb is Fresnel-reflected is reduced, the energy loss due to Fresnel reflection decreases. For example, the energy loss due to the Fresnel reflection decreases from 15.5% to 8.1%.

Moreover, in the present embodiment, since the Z polarizer 70 and the DOE 50 are integrated, the position adjustment of the Z polarizer 70 and the DOE 50 with respect to the optical axis A of the laser beam Lb can be performed with a single moving stage 82.

### 3.4 Modification

Next, the modification of the multi-spot polarization converter 80 will be described. FIG. 15 illustrates the configuration of the multi-spot polarization converter 80 according to a first modification. In the present modification, the Z polarizer 70 is provided inside the substrate 83. The DOE 50 is formed along the exit surface 83b of the substrate 83, similarly to the second embodiment. The Z polarizer 70 and the DOE 50 face each other and are disposed so that the centers coincide with each other.

FIG. 16 illustrates the configuration of the multi-spot polarization converter 80 according to a second modification. In the present modification, the Z polarizer 70 and the DOE 50 are formed by a single optical element 84. For example, the optical element 84 is a DOE configured to accomplish functions of converting the polarization state of the laser beam Lb from the linear polarization to the azimuthal polarization and also splitting the laser beam Lb into the laser beams Lv of different exit angles. The optical element 84 is formed along the exit surface 83b of the substrate 83. In other words, both the Z polarizer 70 and the DOE 50 are formed along the exit surface 83b. The optical element 84 may also be formed along the incident surface 83a of the substrate 83. In other words, both the Z polarizer 70 and the DOE 50 may be formed along the incident surface 83a.

### 4. Electronic Device Manufacturing Method

A laser processing method according to the embodiments can be applied to formation of a through-hole in a substrate provided in an interposer IP in manufacturing of an electronic device 100 below.

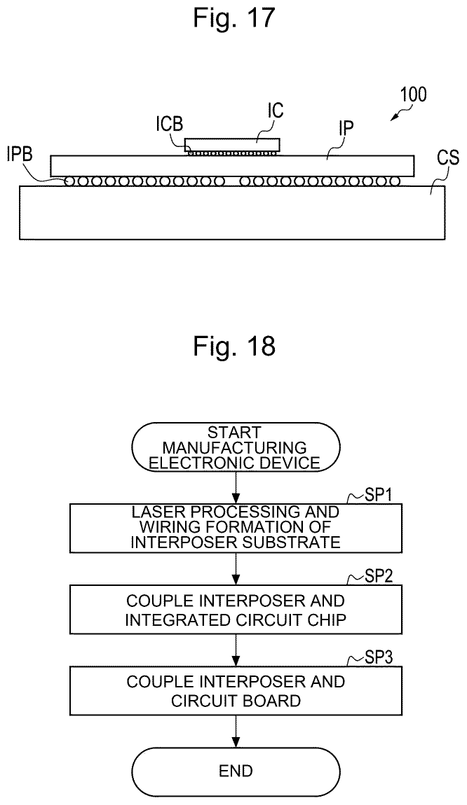

FIG. 17 schematically illustrates a configuration of the electronic device 100. The electronic device 100 illustrated in FIG. 17 includes an integrated circuit chip IC, the interposer IP, and a circuit board CS. The integrated circuit chip IC is, for example, a chip in which an unillustrated integrated circuit is formed on a silicon substrate. The integrated circuit chip IC is provided with a plurality of bumps ICB electrically connected to the integrated circuit.

The interposer IP includes an insulating substrate in which a plurality of unillustrated through-holes are formed, and an unillustrated conductor that electrically connects front and back surfaces of the substrate is provided in each of the through-holes. A plurality of unillustrated lands connected respectively to the bumps ICB are formed on one surface of the interposer IP, and each of the lands is electrically connected to any one of the conductors in the through-holes. A plurality of bumps IPB are provided on the other surface of the interposer IP, and each of the bumps IPB is electrically connected to any one of the conductors in the through-holes.

A plurality of unillustrated lands connected respectively to the bumps IPB are formed on one surface of the circuit board CS. The circuit board CS includes a plurality of terminals electrically connected to the lands.

FIG. 18 illustrates a manufacturing method of the electronic device 100. First, in a first process SP1, laser processing and wiring formation of an interposer substrate forming the interposer IP are performed. The laser processing of the interposer substrate includes forming the through-holes by irradiating the interposer substrate with a pulse laser beam. The wiring formation includes forming a conductive film on an inner wall surface of the through-holes formed in the interposer substrate. By the first process SP1, the interposer IP is produced.

Next, in a second process SP2, the interposer IP and the integrated circuit chip IC are coupled. The second process SP2 includes, for example, disposing the bumps ICB of the integrated circuit chip IC on the lands of the interposer IP and electrically connecting the bumps ICB and the lands.

Then, in a third process SP3, the interposer IP and the circuit board CS are coupled. The third process SP3 includes, for example, disposing the bumps IPB of the interposer IP on the lands of the circuit board CS and electrically connecting the bumps IPB and the lands.

The laser processing processor 40 and the laser processor 38 may be physically configured as hardware to execute various processes included in the present disclosure. For example, the laser processing processor 40 and the laser processor 38 may be a computer including a memory that stores a control program defining the various processes and a processing device that executes the control program. The control program may be stored in one memory, or may be stored separately in a plurality of memories present at physically separate locations, and the various processes may be defined by a combination of the control programs. The processing device may be a general-purpose processing device such as a CPU (Central Processing Unit) or a special-purpose processing device such as a GPU (Graphics Processing Unit).

Alternatively, the laser processing processor 40 and the laser processor 38 may be programmed as software to execute the various processes included in the present disclosure. For example, the laser processing processor 40 and the laser processor 38 may be implemented in a dedicated device such as an ASIC (Application Specific Integrated Circuit) or a programmable device such as a FPGA (Field Programmable Gate Array) that executes the various processes.

The various processes included in the present disclosure may be executed by one computer, one dedicated device, or one programmable device, or may be executed by cooperation of a plurality of computers, a plurality of dedicated devices, or a plurality of programmable devices present at physically separate locations. The various processes may be executed by a combination of at least two of one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined. The terms used throughout the present specification and the appended claims should be interpreted as “non-limiting” terms unless otherwise stated. For example, terms such as “comprise”, “include”, “have”, and “contain” should be interpreted as “not excluding the presence of structural elements other than those described”. Further, indefinite articles “a/an” should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing apparatus that performs hole processing on a workpiece using a pulse laser beam output from a laser apparatus, the laser processing apparatus comprising:
a Z polarizer disposed on an optical path of the pulse laser beam and configured to convert a polarization state of the pulse laser beam to azimuthal polarization;
a diffractive optical element configured to split the azimuthally polarized pulse laser beam transmitted through the Z polarizer into a plurality of laser beams; and
a light condensing optical system configured to generate a plurality of light condensing spots on the workpiece by condensing the laser beams.

2. The laser processing apparatus according to claim 1, wherein
the Z polarizer is disposed so that a center coincides with an optical axis of the pulse laser beam.

3. The laser processing apparatus according to claim 1, wherein
the diffractive optical element is disposed so that a center coincides with an optical axis of the pulse laser beam.

4. The laser processing apparatus according to claim 1, wherein
the Z polarizer is formed by combining a plurality of ½ wave plates of different optical axis directions.

5. The laser processing apparatus according to claim 4, wherein
the number of the ½ wave plates is between 4 and 12.

6. The laser processing apparatus according to claim 1, wherein
the pulse laser beam output from the laser apparatus is linearly polarized, and
the linearly polarized pulse laser beam is incident on the Z polarizer.

7. The laser processing apparatus according to claim 1, comprising
a rotating stage that holds the Z polarizer rotatably with an optical axis of the pulse laser beam as a rotation axis.

8. The laser processing apparatus according to claim 7, wherein
the Z polarizer is disposed so that a center coincides with the rotation axis.

9. The laser processing apparatus according to claim 1, comprising
a first moving stage that holds the Z polarizer movably in a direction orthogonal to an optical axis of the pulse laser beam.

10. The laser processing apparatus according to claim 1, comprising
a second moving stage that holds the diffractive optical element movably in a direction orthogonal to an optical axis of the pulse laser beam.

11. The laser processing apparatus according to claim 1, wherein
the Z polarizer is a polarization converter that sets a polarization direction of the azimuthal polarization to a direction along a circumference.

12. The laser processing apparatus according to claim 1, wherein
the Z polarizer and the diffractive optical element are integrated as a multi-spot polarization converter.

13. The laser processing apparatus according to claim 12, wherein
the multi-spot polarization converter includes a substrate, and
the Z polarizer and the diffractive optical element are formed in the substrate.

14. The laser processing apparatus according to claim 13, wherein
the Z polarizer is formed along an incident surface of the substrate, and
the diffractive optical element is formed along an exit surface of the substrate.

15. The laser processing apparatus according to claim 13, wherein
the Z polarizer is formed inside the substrate, and
the diffractive optical element is formed along an exit surface of the substrate.

16. The laser processing apparatus according to claim 13, wherein
the Z polarizer is formed along an exist surface of the substrate, and
the diffractive optical element is formed along the exit surface of the substrate.

17. The laser processing apparatus according to claim 13, wherein
the Z polarizer is formed along an incident surface of the substrate, and
the diffractive optical element is formed along the incident surface of the substrate.

18. The laser processing apparatus according to claim 12, comprising
a rotating stage that holds the multi-spot polarization converter rotatably with an optical axis of the pulse laser beam as a rotation axis.

19. The laser processing apparatus according to claim 12, comprising
a moving stage that holds the multi-spot polarization converter movably in a direction orthogonal to an optical axis of the pulse laser beam.

20. An electronic device manufacturing method comprising:
producing an interposer by laser processing an interposer substrate with a laser processing apparatus, the laser processing apparatus configured to perform hole processing on a workpiece using a pulse laser beam output from a laser apparatus, the laser processing apparatus including
a Z polarizer disposed on an optical path of the pulse laser beam and configured to convert a polarization state of the pulse laser beam to azimuthal polarization,
a diffractive optical element configured to split the azimuthally polarized pulse laser beam transmitted through the Z polarizer into a plurality of laser beams, and
a light condensing optical system configured to generate a plurality of light condensing spots on the workpiece by condensing the laser beams;
coupling and electrically connecting the interposer and an integrated circuit chip to each other; and
coupling and electrically connecting the interposer and a circuit board to each other.
